(19) United States
(12) Patent Application Publication
(10) Pub. No.: US 2026/0186405 A1
(43) Pub. Date: Jul. 2, 2026

(54) METHOD OF FORMING WIRES

(71) Applicant: Shanghai AVIC Optoelectronics Co., Ltd., Shanghai (CN)

(72) Inventors: Shingo SAIGOU, Kawasaki (JP); Kei MARUYAMA, Kawasaki (JP)

(73) Assignee: Shanghai AVIC Optoelectronics Co., Ltd., Shanghai (CN)

(21) Appl. No.: 19/404,152

(22) Filed: Dec. 1, 2025

(30) Foreign Application Priority Data
Dec. 26, 2024 (JP) 2024-229756

(51) Int. Cl. G03F 7/00; G03F 7/20

(52) U.S. Cl. CPC G03F 7/0035; G03F 7/2002; G03F 7/70008; H10W 70/05

(57) ABSTRACT

A method of forming wires involves a first exposure step of forming a first resist layer on a main surface of a substrate and exposing the first resist layer in a predetermined wiring pattern, a second exposure step of forming a second resist layer on the exposed first resist layer and exposing the second resist layer in the predetermined wiring pattern, a development step of developing the exposed first resist layer and the exposed second resist layer and thus yielding a resist pattern that reflects the predetermined wiring pattern, and a wire formation step of forming wires through plating, based on the resist pattern.

### CROSS-REFERENCE TO RELATED APPLICATIONS

This application claims the benefit of Japanese Patent Application No. 2024-229756, filed on Dec. 26, 2024, the entire disclosure of which is incorporated by reference herein.

### FIELD OF THE INVENTION

This present disclosure relates to a method of forming wires.

### BACKGROUND OF THE INVENTION

Some methods have been known for forming wires by providing a resist pattern on a substrate and plating the substrate having the resist pattern. These methods involve providing a resist layer on the substrate, exposing the resist layer using a mask, and then developing the exposed resist layer, to form a resist pattern.

Recent advancements in wiring pattern resolution require these methods to use a thicker resist layer to form a resist pattern exhibiting a higher aspect ratio. The thicker resist layer, however, inhibits exposure light from arriving at the deep portions of the resist layer, potentially leading to an undesired line/space (L/S) ratio in the resist pattern. That is, the thicker resist layer may impair the pattern fidelity (the accuracy of the L/S ratio) of the resist pattern.

Unexamined Japanese Patent Application Publication No. 2005-5453 discloses a method of fabricating a printed wiring board including circuits exhibiting a high aspect ratio by repeating the formation, exposure, and development of a resist layer. Specifically, the method involves a resist patterning step of exposing and developing a circuit pattern on a resist laminated on a base substrate, and covering non-circuit forming portions with a cross-linking resist. The method also involves a resist stacking step of exposing and developing the same circuit pattern as in the resist patterning step on another laminated resist, and stacking a cross-linking resist on the non-circuit forming portions. This method produces a high-layer resist on the base substrate. The method then involves depositing and stacking conductors through electrolysis or electroless plating to form circuits in the portions not covered with the high-layer resist.

The fabrication method disclosed in Unexamined Japanese Patent Application Publication No. 2005-5453 needs a large number of steps because of the development after every exposure of a resist layer. The method, in which a resist layer is formed on a developed resist layer, often causes the upper resist layer to have uneven properties (uneven thickness and uneven exposure). Unexamined Japanese Patent Application Publication No. 2005-5453 discloses forming a resist pattern exhibiting a high aspect ratio and circuits having a large height, but does not disclose or imply the pattern fidelity of a resist pattern or the accuracy of a circuit pattern.

### SUMMARY OF THE INVENTION

A method of forming wires according to an aspect of the present disclosure includes:
a first exposure step of forming a first resist layer on a main surface of a substrate, and exposing the first resist layer in a predetermined wiring pattern;
a second exposure step of forming a second resist layer on the exposed first resist layer, and exposing the second resist layer in the predetermined wiring pattern;
a development step of developing the exposed first resist layer and the exposed second resist layer, and thus yielding a resist pattern that reflects the predetermined wiring pattern; and
a wire formation step of forming, based on the resist pattern, wires through plating.

It is to be understood that both the foregoing general description and the following detailed description are exemplary and explanatory and are not restrictive of this disclosure.

### BRIEF DESCRIPTION OF DRAWINGS

A more complete understanding of this application can be obtained when the following detailed description is considered in conjunction with the following drawings, in which:

FIG. 1 is a sectional view of a wiring board according to Embodiment 1;

FIG. 2 is a flowchart illustrating a method of forming wires according to Embodiment 1;

FIG. 3 is a sectional view of a seed layer according to Embodiment 1;

FIG. 4 is a sectional view of a first resist layer according to Embodiment 1;

FIG. 5 is a schematic view for describing a first exposure step according to Embodiment 1;

FIG. 6 is a sectional view of a second resist layer according to Embodiment 1;

FIG. 7 is a schematic view for describing a second exposure step according to Embodiment 1;

FIG. 8 is a sectional view of a resist pattern according to Embodiment 1;

FIG. 9 is a schematic view for describing a wire formation step according to Embodiment 1;

FIG. 10 is a schematic view for describing a peeling step according to Embodiment 1;

FIG. 11 is a flowchart illustrating a method of forming wires according to Embodiment 2;

FIG. 12 is a sectional view of a resist pattern according to Embodiment 2;

FIG. 13 is a plan view of a wiring board and a semiconductor chip according to a modification;

FIG. 14 is a sectional view of the wiring board and the semiconductor chip taken along the line A-A of FIG. 13;

FIG. 15 is a photograph illustrating stacked resist layers in an example of the present disclosure;

FIG. 16 is a photograph illustrating a resist layer in a comparative example; and

FIG. 17 is a photograph illustrating wires in the example of the present disclosure.

### DETAILED DESCRIPTION OF THE INVENTION

A method of forming wires according to some embodiments is described below with reference to the accompanying drawings.

### Embodiment 1

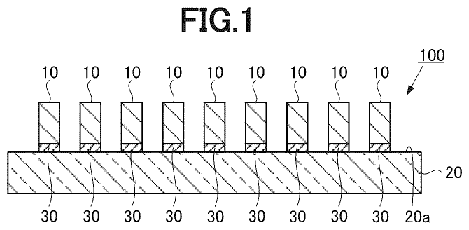

The following describes a method of forming wires 10 according to an embodiment, with reference to FIGS. 1 to 10. The method of forming the wires 10 according to the embodiment can be applied to wires that connect lines, such as data lines and gate lines, to driver integrated circuits (ICs) in an active matrix display device, for example.

The description of the embodiment focuses on an exemplary method of forming the wires 10 in a wiring board 100. As illustrated in FIG. 1, the wiring board 100 includes wires 10, a substrate 20, and a seed layer 30. In the wiring board 100, the seed layer 30 is disposed on a main surface 20a of the substrate 20. The wires 10 are disposed via the seed layer 30 on the main surface 20a of the substrate 20.

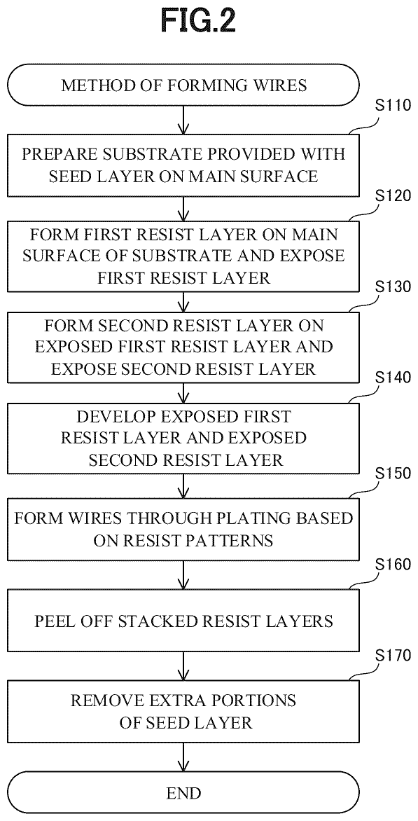

FIG. 2 is a flowchart illustrating a method of forming the wires 10 (method of fabricating the wiring board 100). The method of forming the wires 10 involves a preparation step (Step S110) of preparing the substrate 20 provided with the seed layer 30 on the main surface 20a, a first exposure step (Step S120) of forming a first resist layer 40 on the main surface 20a of the substrate 20 and exposing the first resist layer 40, a second exposure step (Step S130) of forming a second resist layer 50 on the exposed first resist layer 40a and exposing the second resist layer 50, and a development step (Step S140) of developing the exposed first resist layer 40a and the exposed second resist layer 50a. The method of forming the wires 10 further involves a wire formation step (Step S150) of forming the wires 10 through plating on the basis of a resist pattern RP formed in the development step (Step S140), a peeling step (Step S160) of peeling off stacked resist layers 60, and a removal step (Step S170) of removing the extra portions of the seed layer 30.

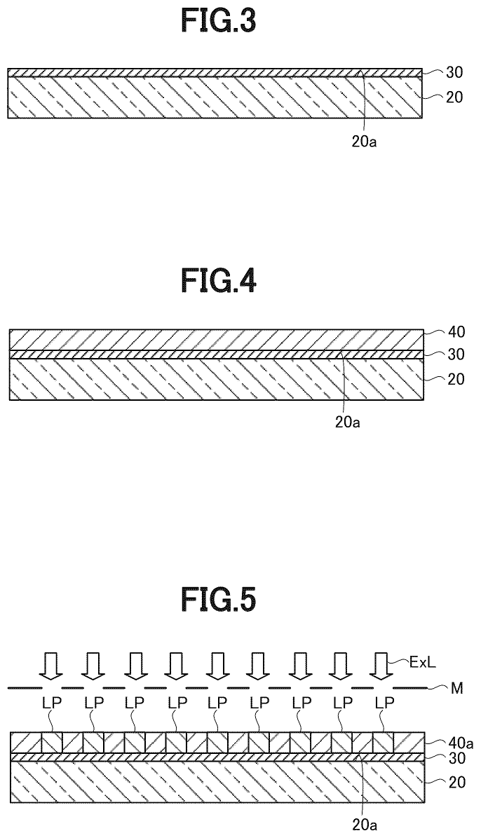

The preparation step (Step S110) involves preparing the substrate 20 provided with the seed layer 30 on the main surface 20a, as illustrated in FIG. 3. A typical example of the substrate 20 is a glass substrate. The seed layer 30 is made of an electrically conductive metal, such as copper (Cu), nickel (Ni), or titanium (Ti). The seed layer 30 is provided on the main surface 20a of the substrate 20, for example, through spattering. The seed layer 30 has a thickness of 0.05 μm to 0.5 μm, for example.

Referring back to FIG. 2, the first exposure step (Step S120) first involves forming a first resist layer 40 on the main surface 20a of the substrate 20, as illustrated in FIG. 4. The first resist layer 40 is made of a positive resist, for example. Specifically, the first resist layer 40 is provided on the seed layer 30 (that is, on the main surface 20a of the substrate 20) through spin coating or slit coating, for example. The first resist layer 40 has a thickness of 5 μm, for example.

The first resist layer 40 is then pre-baked, and is exposed using a mask M in a predetermined wiring pattern LP, as illustrated in FIG. 5. This step produces an exposed first resist layer 40a. The first resist layer 40 is preferably exposed to exposure light ExL having a wavelength (that is, a photosensitive wavelength of the first resist layer 40) equal to or higher than 300 nm. Examples of the exposure light ExL include g-line (436 nm), h-line (405 nm), and i-line (365 nm). The wiring pattern LP has a line/space (L/S) ratio of 5 μm/5 μm, for example.

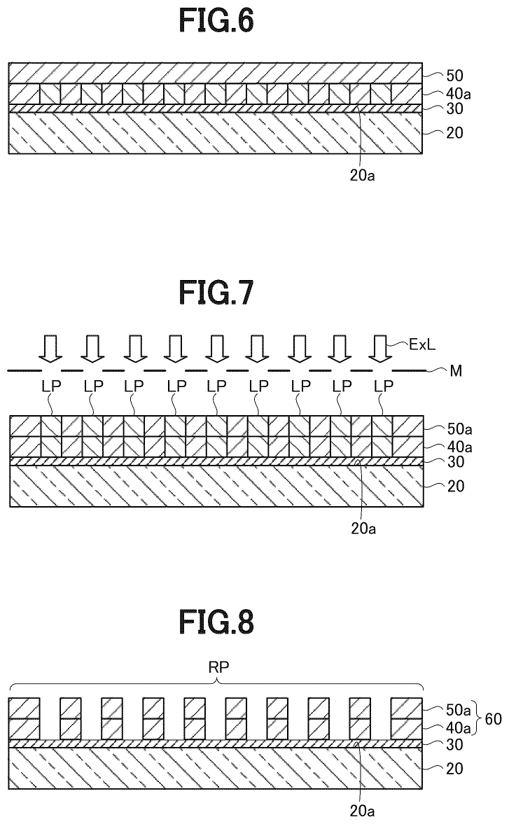

Referring back to FIG. 2, the second exposure step (Step S130) first involves forming a second resist layer 50 on the exposed first resist layer 40a, as illustrated in FIG. 6. The second resist layer 50 is made of a positive resist. The first resist layer 40 and the second resist layer 50 are made of the same resist material in the embodiment.

The second resist layer 50 is provided on the exposed first resist layer 40a through spin coating or slit coating, for example. The second resist layer 50 has a thickness of 5 μm, for example.

The second resist layer 50 is then pre-baked, and is exposed using the mask M in the wiring pattern LP, as illustrated in FIG. 7. This step produces an exposed second resist layer 50a stacked on the exposed first resist layer 40a. The mask M is identical to the mask M used in the first exposure step (Step S120) in the embodiment. The mask M is aligned to the proper position such that the wiring pattern LP in this step is located at the same position as the wiring pattern LP in the first exposure step (Step S120) in plan view of the substrate 20.

The second resist layer 50 is exposed to exposure light ExL having the same wavelength as the wavelength of the exposure light ExL in the first exposure step (Step S120). Preferably, the exposure dose (mJ/cm²) for the second resist layer 50 is greater than the exposure dose (mJ/cm²) for the first resist layer 40. The focal positions are adjusted separately in the first exposure step (Step S120) and the second exposure step (Step S130), for example, by means of the automatic focus mechanism of the exposure tool.

Referring back to FIG. 2, the development step (Step S140) involves forming a resist pattern RP that reflects the wiring pattern LP, by developing the exposed first resist layer 40a and the exposed second resist layer 50a with a developing solution. As illustrated in FIG. 8, the resist pattern RP reflecting the wiring pattern LP is formed of the stacked resist layers 60 made of the exposed first resist layer 40a and the exposed second resist layer 50a, on the main surface 20a of the substrate 20.

In the embodiment, the resist pattern RP is formed of the two layers (stacked resist layers 60) including the first resist layer 40 and the second resist layer 50. This configuration allows the resist pattern RP (stacked resist layers 60) to have a larger height, and exhibits a higher aspect ratio (ratio between the space in the stacked resist layers 60 and the height of the stacked resist layers 60) for formation of the wires 10. Specifically, the resist pattern RP in this embodiment has a height of 10 μm and exhibits an aspect ratio of 1:2. The first resist layer 40 and the second resist layer 50 are exposed separately. This separate exposure allows the exposure light ExL to arrive at the deep portions of each of the first resist layer 40 and the second resist layer 50, and can thus improve the pattern fidelity (that is, the accuracy of the L/S ratio). In other words, the separate exposure can yield the resist pattern RP exhibiting high pattern fidelity. Furthermore, the exposed first resist layer 40a and the exposed second resist layer 50a are simultaneously developed. This simultaneous development can reduce the number of steps of forming the resist pattern RP, and facilitate formation of the resist pattern RP.

In the embodiment, the first resist layer 40 and the second resist layer 50 are exposed to light, such as g-line, h-line, or i-line. The method in the embodiment can thus form the resist pattern RP exhibiting a high aspect ratio for formation of the wires 10, using existing exposure tools and existing resist materials.

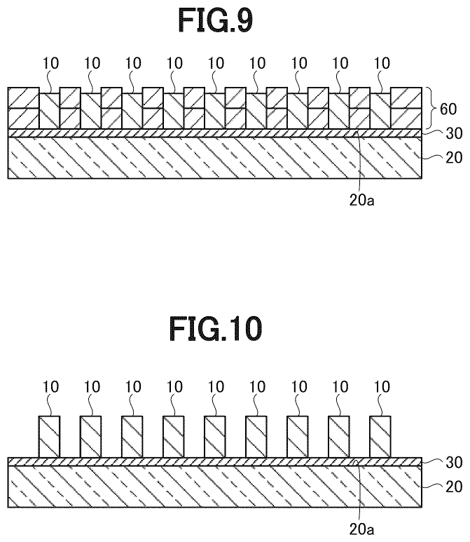

Referring back to FIG. 2, the wire formation step (Step S150) involves forming wires 10 on the main surface 20a of the substrate 20 on the basis of the resist pattern RP, through well-known electrolytic plating. Specifically, applying an electric current to the seed layer 30 in a plating bath causes a conductor (for example, copper) to be deposited on the seed layer 30. The current application thus provides wires 10 on the portions of the seed layer 30 not covered with the stacked resist layers 60, as illustrated in FIG. 9.

The method in the embodiment can achieve a higher aspect ratio of the resist pattern RP for formation of the wires 10, and thus enable a higher aspect ratio of the wires 10 formed through plating on the basis of the resist pattern RP. The resist pattern RP exhibiting high pattern fidelity results in the wires 10 exhibiting high pattern fidelity (high accuracy of the L/S ratio).

Referring back to FIG. 2, the peeling step (Step S160) involves peeling off the stacked resist layers 60 from the seed layer 30 with a stripping solution. This peeling removes the stacked resist layers 60 from the seed layer 30, and causes the portions of the seed layer 30 that were located below the stacked resist layers 60 to appear, as illustrated in FIG. 10.

Referring back to FIG. 2, the removal step (Step S170) involves removing the uncovered extra portions of the seed layer 30 from the main surface 20a of the substrate 20, through etching. The above-described process forms the wires 10 on the main surface 20a of the substrate 20, and produces the wiring board 100 (FIG. 1).

As described above, the method of forming the wires 10 can readily form the wires 10 exhibiting high pattern fidelity and a high aspect ratio.

### Embodiment 2

In Embodiment 1, the single second resist layer 50 (exposed second resist layer 50a) is stacked on the exposed first resist layer 40a. Multiple second resist layers 50 may be stacked on the exposed first resist layer 40a.

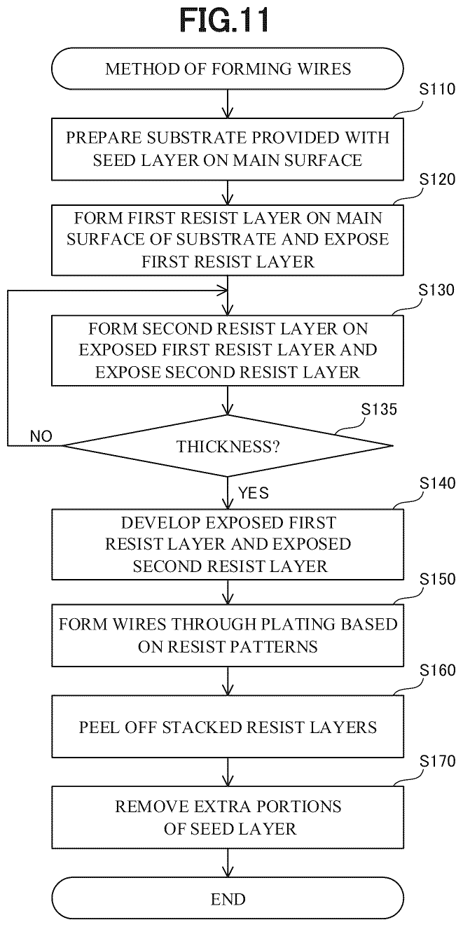

FIG. 11 is a flowchart illustrating a method of forming the wires 10 (method of fabricating the wiring board 100) according to another embodiment. The method of forming the wires 10 according to the embodiment involves the preparation step (Step S110), the first exposure step (Step S120), the second exposure step (Step S130), an evaluation step (Step S135) for evaluating the thickness, and the development step (Step S140). The method of forming the wires 10 according to the embodiment also involves the wire formation step (Step S150), the peeling step (Step S160), and the etching step (Step S170).

The preparation step (Step S110), the first exposure step (Step S120), the wire formation step (Step S150), the peeling step (Step S160), and the etching step (Step S170) in the embodiment are identical to those in Embodiment 1. The description thus focuses on the second exposure step (Step S130), the evaluation step (Step S135), and the development step (Step S140) in the embodiment.

In this embodiment, the second exposure step (Step S130) is repeated until the sum of the thickness of the exposed first resist layer 40a and the thickness of the exposed second resist layer 50a reaches a predetermined value (desired thickness).

The second exposure step (Step S130) executed for the first time involves forming an initial second resist layer 50 on the exposed first resist layer 40a, pre-baking the initial second resist layer 50, and then exposing the initial second resist layer 50, like the second exposure step (Step S130) in Embodiment 1. This step produces an exposed initial second resist layer 50a.

The evaluation step (Step S135) involves evaluating the sum of the thickness of the exposed first resist layer 40a and the thickness of the exposed second resist layer 50a. When evaluating that the sum of the thickness of the exposed first resist layer 40a and the thickness of the exposed second resist layer 50a is smaller than the predetermined value, the step evaluates that the sum of the thickness of the exposed first resist layer 40a and the thickness of the exposed second resist layer 50a has not reached the predetermined value (Step S135; NO). When evaluating that the sum has not reached the predetermined value, the method of forming the wires 10 according to the embodiment returns to the second exposure step (Step S130).

The second exposure steps (Step S130) executed for the second and following times involves forming another second resist layer 50 on the existing exposed second resist layer 50a on the exposed first resist layer 40a, and exposing the other second resist layer 50. Specifically, the step involves forming another second resist layer 50 on the existing exposed second resist layer 50a, and exposing the currently formed second resist layer 50. These steps produce multiple exposed second resist layers 50a on the exposed first resist layer 40a.

The second resist layers 50 formed in the second exposure steps (Step S130) executed for the second and following times are made of the same resist material as the initial second resist layer 50. The second exposure steps (Step S130) executed for the second and following times use the mask M identical to the mask M used in the first exposure step (Step S120). In the embodiment, the exposure dose for the second resist layer 50 is preferably greater than the exposure dose for the first resist layer 40.

The evaluation step (Step S135) evaluates that the sum of the thickness of the exposed first resist layer 40a and the thicknesses of the exposed second resist layers 50a has reached the predetermined value, when the sum of the thickness of the exposed first resist layer 40a and the thicknesses of the exposed second resist layers 50a is equal to the predetermined value (Step S135; YES). When evaluating that the sum has reached the predetermined value, the method of forming the wires 10 according to the embodiment proceeds to the development step (Step S140).

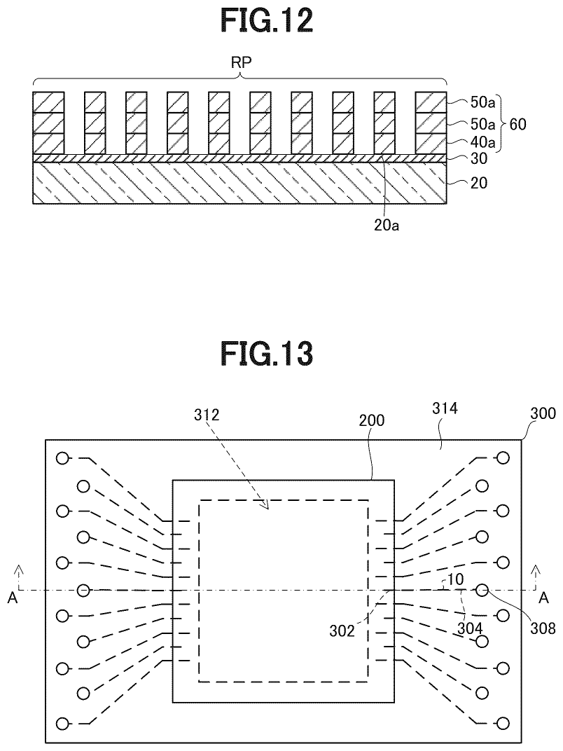

The development step (Step S140) involves developing the exposed first resist layer 40a and the exposed second resist layer 50a with a developing solution. This step causes the stacked resist layers 60 to yield the resist pattern RP that reflects the wiring pattern LP on the main surface 20a of the substrate 20, as illustrated in FIG. 12. FIG. 12 illustrates an example of the resist pattern RP (stacked resist layers 60) having experienced the second exposure steps (Step S130) twice.

In the embodiment, the resist pattern RP is formed of the stacked resist layers 60 including the first resist layer 40 and the multiple second resist layers 50. This configuration allows the resist pattern RP to have a further increased height and exhibit a much higher aspect ratio for formation of the wires 10. For example, the method in the embodiment can achieve the aspect ratio of the resist pattern RP equal to or higher than 1:2 for formation of the wires 10.

The method in the embodiment can achieve a higher aspect ratio of the resist pattern RP for formation of the wires 10, and thus enable a higher aspect ratio of the wires 10. The simultaneous development of the exposed first resist layer 40a and the exposed second resist layers 50a can reduce the number of steps of forming the wires 10. In addition, the separate light exposure of the first resist layer 40 and the second resist layers 50 allows the exposure light ExL to arrive at the deep portions of each of the first resist layer 40 and the second resist layers 50. These features can facilitate formation of the wires 10 exhibiting high pattern fidelity and a high aspect ratio.

As described above, the method of forming the wires 10 according to the embodiment can also facilitate formation of the wires 10 exhibiting high pattern fidelity and a high aspect ratio.

### Modifications

The above-described embodiments may be modified in various manners within the gist of the present disclosure.

In the above-described embodiments, the first resist layer 40 and the second resist layer 50 are made of the same resist material. The first resist layer 40 and the second resist layer 50 may also be made of mutually different resist materials. In the case of multiple execution of the second exposure steps (Step S130), the second exposure steps (Step S130) may apply mutually different resist materials.

In the above-described embodiments, the first exposure step (Step S120) and the second exposure step (Step S130) apply the positive resist. The first exposure step (Step S120) and the second exposure step (Step S130) may apply a resist material other than the positive resist. For example, the first exposure step (Step S120) and the second exposure step (Step S130) may apply a negative resist. Alternatively, the first exposure step (Step S120) and the second exposure step (Step S130) may apply a dry film resist.

In the above-described embodiments, the first resist layer 40 and the second resist layer 50 are provided through spin coating or slit coating, for example. The first resist layer 40 and the second resist layer 50 may also be provided by another well-known method (for example, dipping method) depending on the resist material that constitutes the first resist layer 40 and the second resist layer 50.

The mask M used in the first exposure step (Step S120) may be different from the mask M used in the second exposure step (Step S130).

The wire formation step (Step S150) in the above-described embodiments involves forming wires 10 through electrolytic plating. In the wire formation step (Step S150), the wires 10 may also be formed through another plating method.

For example, the wires 10 may be formed through electroless plating. In this modification, the wiring board 100 may lack the seed layer 30. Also, the substrate 20 prepared in the preparation step (Step S110) may lack the seed layer 30.

The substrate 20 is not necessarily a glass substrate. The substrate 20 may also be a resin film having electrical insulating properties.

The method of forming the wires 10 can also be applied to fabrication of a wiring board 300 for connecting signal wires of a semiconductor chip 200 to external components. In this modification, connecting lines 302 for connecting the signal wires of the semiconductor chip 200 to the wires 10 of the wiring board 300, connecting lines 304 for connecting the wires 10 of the wiring board 300 to external devices, and other components are disposed on the wires 10 via an insulating layer 310. The wires 10 of the wiring board 300 serve as lead wires.

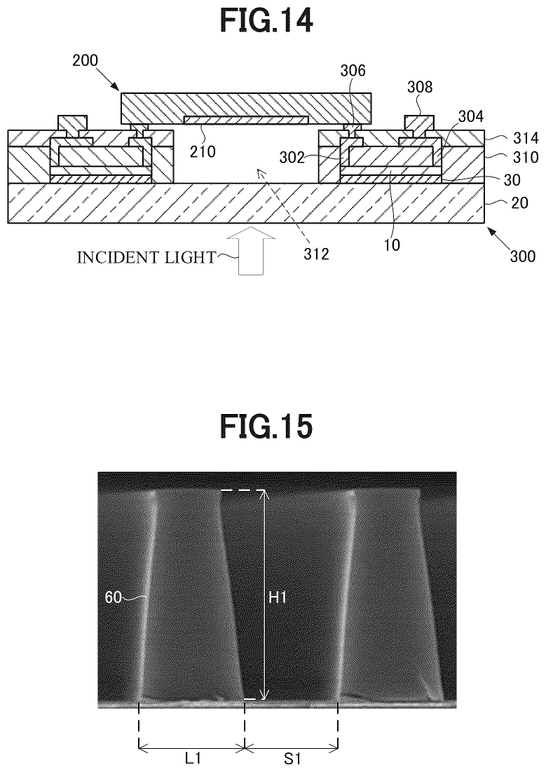

For example, as illustrated in FIGS. 13 and 14, the semiconductor chip 200 having a light receiving element 210 is mounted on the wiring board 300. The semiconductor chip 200 is mounted on the wiring board 300 such that the light receiving element 210 faces the wiring board 300. The light receiving element 210 of the semiconductor chip 200 and the substrate 20 of the wiring board 300 are provided with no component therebetween and thus define an opening 312. This structure causes the substrate 20 of the wiring board 300 to seal the light receiving element 210 and thus protects the light receiving element 210.

The wiring board 300 has a fan-out structure that connects the signal wires of the semiconductor chip 200 to external terminals 308 of the wiring board 300, via terminals (not illustrated) connected to the signal wires of the semiconductor chip 200 and chip mounting terminals 306 of the wiring board 300.

The wires 10 of the wiring board 300 are formed on the substrate 20 by the same procedure as in the above-described embodiments. The insulating layer (for example, polyimide layer) 310 is formed on the wires 10 of the wiring board 300. The connecting lines 302 and 304 is formed on the insulating layer 310. The connecting lines 302 and 304 are connected to the wires 10 via through holes provided in the insulating layer 310.

The connecting lines 302 are connected to the chip mounting terminals 306 disposed on an insulating layer 314, and the chip mounting terminals 306 are connected to the terminals of the semiconductor chip 200. The connecting lines 304 are connected to the external terminals 308 disposed on the insulating layer 314. The external terminals 308 are connected to external devices and external controllers, for example.

Recent thinning of semiconductors and downsizing of the semiconductor chip 200 require shorter spacing between the chip mounting terminals 306 for mounting of the semiconductor chip 200 and the use of thinner wires (lead wires) 10. Such thinner wires 10 inevitably have higher resistances and may impair the quality of signals. The method according to the present disclosure can form high-density wires 10 while maintaining the sufficiently low resistances of the wires 10, because the formed wires 10 exhibit high pattern fidelity and a high aspect ratio.

The above-described preferred embodiments are not to be construed as limiting the scope of the present disclosure. The scope of the present disclosure is defined by the following claims and equivalents thereof.

### Example

The following describes the present disclosure more specifically on the basis of an example, which is not to be construed as limiting the scope of the present disclosure.

In this example, wires 10 were formed by the method of forming the wires 10 in Embodiment 1 (FIG. 2).

Specifically, in the preparation step (Step S110), a substrate (glass substrate) 20 was prepared. The substrate 20 includes a seed layer 30 made of copper and having a thickness of 0.05 μm to 0.5 μm.

In the first exposure step (Step S120), the main surface 20a of the substrate 20 was provided with a first resist layer 40 (PMER P-WG series, available from TOKYO OHKA KOGYO CO., LTD.) having a thickness of 6.5 μm through spin coating, followed by a pre-baking treatment at 110° C. for 120 seconds. The first resist layer 40 was then exposed using the mask M, in a wiring pattern LP having an L/S ratio of 5 μm/5 μm. The exposure light ExL contained g-line and h-line. The exposure light ExL may be g-line alone or h-line alone.

The second exposure step (Step S130) involved forming a second resist layer 50, pre-baking the second resist layer 50, and then exposing the second resist layer 50, under the same conditions as those in the first exposure step (Step S120).

In the development step (Step S140), the exposed first resist layer 40a and the exposed second resist layer 50a were developed with a 2.38% tetramethylammonium hydroxide (TMAH) aqueous solution (by the puddle developing method for 300 seconds).

In the wire formation step (Step S150), wires 10 were formed through electrolytic Cu plating with a sulfuric acid copper solution. In the peeling step (Step S160), the stacked resist layers 60 were peeled off from the seed layer 30 with a stripping solution. In the removal step (Step S170), the extra portions of the seed layer 30 were removed from the main surface 20a of the substrate 20 through etching.

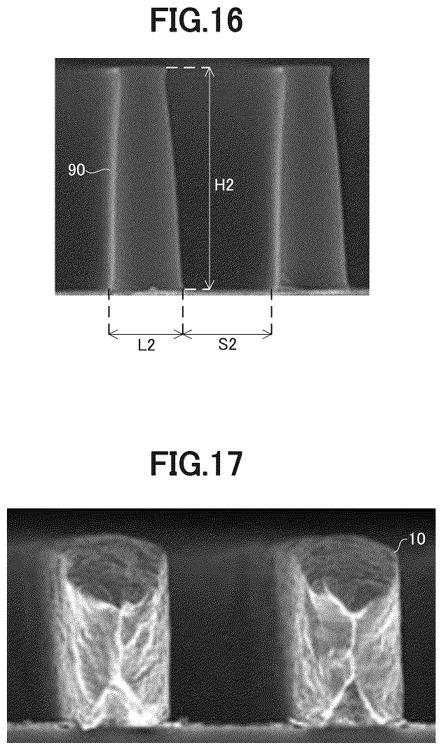

FIG. 15 illustrates the stacked resist layers 60 in the resist pattern RP resulting from the development step (Step S140). FIG. 16 illustrates a resist layer 90 in a resist pattern resulting from a method in a comparative example. FIG. 17 illustrates the wires 10 formed in the example of the present disclosure. The method in the comparative example involves forming a resist layer having a thickness of 13 μm, exposing the formed resist layer (into an L/S ratio of 5 μm/5 μm), and developing the resist layer, thereby yielding a resist pattern.

The stacked resist layers 60 in the example of the present disclosure exhibited a line width L1 of 5.2 μm and a space S1 of 4.9 μm. That is, the L/S ratio in the example of the present disclosure was 5.2/4.9. The stacked resist layers 60 in the example of the present disclosure had a height H1 of 11.5 μm. The stacked resist layers 60 thus exhibited an aspect ratio (4.9/11.5) of 1:2.3 for formation of the wires 10. In contrast, the resist layer 90 in the resist pattern in the comparative example exhibited a line width L2 of 4.5 μm and a space S2 of 5.6 μm. That is, the L/S ratio in the comparative example was 4.5/5.6. The resist layer 90 in the comparative example had a height H2 of 13.7 μm. The resist layer 90 thus had an aspect ratio (5.6/13.7) of 1:2.4 for formation of the wires 10.

The example in the present disclosure was able to readily yield the resist pattern RP exhibiting high pattern fidelity and a high aspect ratio for formation of the wires 10. The stacked resist layers 60 in the example in the present disclosure had no visible boundary between the first resist layer 40 and the second resist layer 50 (FIG. 15), which implied successful formation of a preferable resist pattern RP in the example.

The example in the present disclosure was able to readily form the wires 10 exhibiting high pattern fidelity and a high aspect ratio, as illustrated in FIG. 17.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

1. A method of forming wires, the method comprising:
a first exposure step of forming a first resist layer on a main surface of a substrate, and exposing the first resist layer in a predetermined wiring pattern;
a second exposure step of forming a second resist layer on the exposed first resist layer, and exposing the second resist layer in the predetermined wiring pattern;
a development step of developing the exposed first resist layer and the exposed second resist layer, and thus yielding a resist pattern that reflects the predetermined wiring pattern; and
a wire formation step of forming, based on the resist pattern, wires through plating.

2. The method of forming wires according to claim 1, wherein the second exposure step is repeated multiple times.

3. The method of forming wires according to claim 1, wherein the first exposure step and the second exposure step use exposure light having a wavelength equal to or higher than 300 nm.

4. The method of forming wires according to claim 1, wherein the resist pattern exhibits an aspect ratio equal to or higher than 1:2.
